(19) United States
(12) Patent Application Publication
(10) Pub. No.: US 2009/0176372 A1
(43) Pub. Date: Jul. 9, 2009

(54) CHEMICAL MECHANICAL POLISHING SLURRY AND SEMICONDUCTOR DEVICE MANUFACTURING METHOD

(76) Inventors: Gaku MINAMIHABA, Kanagawa (JP); Nobuyuki KURASHIMA, Kanagawa (JP); Atsushi SHIGETA, Mie (JP); Yoshikuni TATEYAMA, Kanagawa (JP); Hiroyuki YANO, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/339,435

(22) Filed: Dec. 19, 2008

(30) Foreign Application Priority Data
Dec. 27, 2007 (JP) 2007-337248

(51) Int. Cl. H01L 21/465; C09K 13/00; H01L 21/4763

(52) U.S. Cl. 438/693; 252/79.1; 438/584; 257/E21.485; 257/E21.495

(57) ABSTRACT

A chemical mechanical polishing slurry includes at least one water-soluble polymer selected from a group consisting of polyacrylic acid, polymethacrylic acid and a salt thereof each having a weight-average molecular weight of 1,000,000 to 10,000,000, β-cyclodextrin, colloidal silica, and water.

### CROSS-REFERENCE TO RELATED APPLICATIONS

This application is based upon and claims the benefit of priority from the prior Japanese Patent Application No. 2007-337248, filed on Dec. 27, 2007; the entire contents of which are incorporated herein by reference.

### BACKGROUND OF THE INVENTION

1. Field of the Invention

The present invention relates to a chemical mechanical polishing slurry and a semiconductor device manufacturing method using the slurry.

2. Description of the Related Art

Recently, fine processing of wirings to be formed has been progressed along with increasing density of semiconductor devices. To obtain finer wirings, a technique called a damascene process has been known. The damascene process is a process of forming a wiring such as Cu in an insulating film by forming a wiring concave portion by reactive ion etching (RIE) or the like, on an insulating film arranged on a semiconductor substrate, then embedding a wiring material in the concave portion, and removing the redundant wiring material deposited on a portion other than the concave portion by chemical mechanical polishing (hereinafter, CMP).

When Cu or Cu alloy is used as a wiring material, a barrier metal film made of Ta, TaN, Ti, TiN, Ru or the like is usually formed between Cu or Cu alloy and an insulating film to prevent migration of Cu atoms to the insulating film.

Various slurries containing components such as abrasive grains, a metal oxidizing agent, a metal oxide solubilizer, an anticorrosion agent, a surfactant, or a water-soluble polymer have been proposed as a CMP slurry that can be used in the CMP of the wiring material or the barrier metal film described above. For example, JP-A 2006-66874 (KOKAI) discloses a polishing composition for CMP, including abrasive grains, an oxidizing agent, an organic acid, an anticorrosion agent, a surfactant, and a pH adjusting agent, and has pH in the range of 5 to 10. JP-A 2007-13059 (KOKAI) discloses a polishing composition for CMP, which includes 0.1 to 10% by mass of abrasive grains, 0.01 to 10% by mass of ammonium persulfate, 0.01 to 5% by mass of oxalic acid, 0.0001 to 5% by mass of benzotriazole, 0.001 to 10% by mass of dodecylbenzenesulfonic acid and/or dodecylbenzenesulfonate, 0.001 to 10% by mass of polyvinyl pyrrolidone, and a pH adjusting agent that is a water-soluble basic compound and which has pH in the range of 8 to 12. Also, it has been disclosed that in these conventional CMP slurries, cyclodextrin can be also used as an optional component.

Recently, utilization of a material of low dielectric constant in the insulating film has been progressing. However, its insulating film of low dielectric constant (first insulating film) is, when directly subjected to RIE processing for forming a concave portion, easily damaged upon removal of a mask for RIE processing or the like. Accordingly, an insulating film of relatively high dielectric constant, such as SiO₂ film, is deposited as a second insulating film (cap insulating film) on the first insulating film, and a concave portion is formed from the second insulating film to the first insulating film.

Because the second insulating film has a high dielectric constant, when the insulating film is left as an interlayer insulating film surrounding a wiring formed on the concave portion, it will deteriorate electric characteristics of the wiring. Hence, the removal of a redundant portion of the deposited wiring material by CMP as described above is preferably followed by complete removal of the second insulating film by a CMP process.

In this case, laminated films to be removed by the CMP are three kinds of films, that is, a redundant portion of the wiring material-deposited film, the second insulating film used as a cap insulating film, and the barrier metal film. At the final stage of CMP, the surface of the first insulating film among concave portions is to be exposed, and thus the films to be subjected to CMP from the start of polishing to the end of polishing are four kinds of films, that is, the three kinds of films plus the first insulating film. At the early stage of CMP, only a redundant portion of the wiring material-deposited film consisting of Cu or Cu alloy is polished, and at the next stage, the barrier metal film, the second insulating film and the surface of the first insulating film are polished in this order.

When the same polishing agent is used, the film consisting of Cu or Cu alloy, the second insulating film consisting of SiO₂, the barrier metal film consisting of a metal such as Ta, and the first insulating film consisting of a low dielectric material such as SiOC are polished at considerably different rates. Accordingly, the polishing of the films at such different rates is handled by performing CMP at two stages, that is, a first chemical mechanical polishing process of removing a redundant portion of the wiring material-deposited film consisting of Cu and Cu alloy (hereinafter, “first CMP process”) and a second chemical mechanical polishing process of removing the remaining second insulating film and barrier metal film (hereinafter, “second CMP process”).

In the second CMP process, the barrier metal film, the second insulating film, and the surface of the first insulating film are sequentially polished, and thus it is desired that chemical mechanical polishing slurry (hereinafter, “CMP slurry”) used in polishing has excellent polishing performance for any of the films. Particularly, at the final stage of the second CMP process, the exposed surface of the second insulating film, the exposed surface of the barrier metal film formed along the side wall of the concave portion, and the exposed surface of the wiring material layer in the concave portion should be simultaneously polished and finished to planarize the entire surface of a resulting semiconductor wafer.

### SUMMARY OF THE INVENTION

According to one aspect of the present invention, a chemical mechanical polishing slurry includes at least one water-soluble polymer selected from a group consisting of polyacrylic acid, polymethacrylic acid and a salt thereof each having a weight-average molecular weight of 1,000,000 to 10,000,000; β-cyclodextrin; colloidal silica; and water.

According to another aspect of the present invention, a semiconductor device manufacturing method includes forming a first insulating film above a semiconductor substrate; forming, on the first insulating film, a second insulating film having a higher dielectric constant than that of the first insulating film; forming a wiring concave portion from the second insulating film to the first insulating film; forming a barrier metal film on an inner surface of the concave portion and a surface of the second insulating film; depositing copper or copper alloy on the barrier metal film so as to embed the concave portion covered with the barrier metal film, thereby forming a wiring material-deposited layer; polishing flatly and removing the wiring material-deposited layer by a first chemical mechanical polishing until the barrier metal film is exposed; and polishing flatly and removing the barrier metal film and the second insulating film by a second chemical mechanical polishing until the first insulating film is exposed, wherein the second chemical mechanical polishing is conducted by using a chemical mechanical polishing slurry including at least one water-soluble polymer selected from a group consisting of polyacrylic acid, polymethacrylic acid, and a salt thereof each having a weight-average molecular weight of 1,000,000 to 10,000,000, β-cyclodextrin, colloidal silica, and water.

### BRIEF DESCRIPTION OF THE DRAWINGS

FIG. 1 is a schematic diagram for explaining a semiconductor device manufacturing method according to an embodiment of the present invention, and is a schematic cross-section of a state that wiring-forming concave portions are formed in first and second insulating films laminated on an insulating layer formed on a semiconductor substrate;

FIG. 2 is a schematic diagram for explaining the semiconductor device manufacturing method according to an embodiment of the present invention, and is a schematic cross-section of a state that a barrier metal film is laminated on an entire surface of the insulating film having concave portions formed therein;

FIG. 3 is a schematic diagram for explaining the semiconductor device manufacturing method according to an embodiment of the present invention, and is a schematic cross-section of a state that a wiring material is deposited on an entire surface of the barrier metal film to embed the wiring material in the concave portions;

FIG. 4 is a schematic diagram for explaining the semiconductor device manufacturing method according to an embodiment of the present invention, and is a schematic cross-section of a state that a redundant portion of the wiring material-deposited layer is polished by a first CMP process;

FIG. 5 is a schematic diagram for explaining the semiconductor device manufacturing method according to an embodiment of the present invention, and is a schematic cross-section of a state that after starting a second CMP process, the barrier metal film is flatly polished and the second insulating film under the barrier metal film is exposed;

FIG. 6 is a schematic diagram for explaining the semiconductor device manufacturing method according to an embodiment of the present invention, and is a schematic cross-section of a state that the barrier metal film and the second insulating film under the barrier metal film are flatly polished by the second CMP process and the first insulating film is exposed; and

FIG. 7 is a schematic diagram of a polishing apparatus used for the semiconductor device manufacturing method according to an embodiment of the present invention.

### DETAILED DESCRIPTION OF THE EMBODIMENTS

Exemplary embodiments of a chemical mechanical polishing slurry and a semiconductor device manufacturing method according to the present invention will be explained below in detail with reference to the accompanying drawings. The present invention is not limited to the following descriptions and various changes can be appropriately made without departing from the scope of the invention.

Major problems that are obstacles to improvement in surfaces to be polished by CMP in forming a wiring in an interlayer insulating film of low dielectric constant are as follows:

(i) reduction in polishing friction of an SiO₂ film that is a cap insulating film (second insulating film) usually deposited on an interlayer insulating film of low dielectric constant (first insulating film), the reduction being assumed to occur by adsorbing onto the SiO₂ film an organic acid in CMP slurry used in a first CMP process;
(ii) generation of an excessively polished site called “fang”, which easily occurs on the edge of a region having a broad area of the exposed surface of the first insulating film consisting of a hydrophobic low-dielectric material; and
(iii) generation of a state of a partially scraped surface of a wiring layer (hereinafter, “scratch”).

When the first CMP process and a second CMP process are continuously performed with a same polishing table, these problems become particularly significant and thus become as obstacles to improve throughput in manufacturing semiconductor devices.

The above problems can be solved by one embodiment of the present invention described below in detail.

The CMP slurry of the present embodiment is a polishing composition which is preferably used in the second CMP process among the first and second CMP processes performed in a semiconductor device manufacturing method in which a wiring layer is formed in an insulating film on a semiconductor substrate by a damascene process.

As described above, CMC slurry of the present embodiment is a polishing composition preferably used in the second CMP process (for descriptive convenience, referred to as “the second CMP slurry”) and has basic elemental materials such as abrasive grains or the like, constituting CMP slurry used in the first CMP process (for descriptive convenience, referred to as “the first CMP slurry”) and further has a composition containing, as essential components, β-cyclodextrin, and at least one water-soluble polymer selected from a group consisting of polyacrylic acid, polymethacrylic acid, and a salt thereof having a weight-average molecular weight of 1,000,000 to 10,000,000.

One example of the first CMP slurry composition is described first in detail, and essential components of the second CMP slurry (the CMP slurry of the embodiment) are then described in detail.

The first CMP slurry used in the first CMP process in the semiconductor device manufacturing method according to the present embodiment is not particularly limited, and CMP slurry conventionally used in the first CMP process can be used. For example, a polishing composition having the following composition is used as the first CMP slurry.

### [First CMP Slurry]

The first CMP slurry is suitable for use in the first CMP process of removing an unnecessary portion of a wiring material-deposited film consisting of Cu or Cu alloy, and contains water, a water-insoluble Cu complex-forming agent, a water-soluble Cu complex-forming agent, an oxidizing agent, a surfactant, colloidal silica, and a pH adjusting agent.

### (Water-Insoluble Cu Complex-Forming Agent)

As a complex-forming agent that forms a water-insoluble or water-sparingly-soluble complex with a metal such as Cu, the agent includes, for example, a heterocyclic compound having a heterocyclic 6- or 5-membered ring containing at least one nitrogen atom. More specific examples include quinaldinic acid, quinolinic acid, benzotriazole, benzimidazole, 7-hydroxy-5-methyl-1,3,4-triazaindolizine, nicotinic acid and picolinic acid. The content of the water-insoluble Cu complex-forming agent is preferably equal to or more than 0.0005% by mass to equal to or less than 2.0% by mass based on the total amount of the CMP slurry. When the content of the water-insoluble Cu complex-forming agent is equal to or more than 0.0005% by mass to equal to or less than 2.0% by mass, the surface of a wiring layer to be polished can be prevented from dishing, and a favorable rate of polishing of Cu can be simultaneously achieved. The content of the water-insoluble Cu complex-forming agent is more preferably equal to or more than 0.0075% by mass to equal to or less than 1.5% by mass based on the total amount of the first CMP slurry.

### (Water-Soluble Cu Complex-Forming Agent)

The complex-forming agent that forms a water-soluble complex with a metal such as Cu functions as a polishing accelerator includes, for example, formic acid, succinic acid, lactic acid, acetic acid, tartaric acid, fumaric acid, glycolic acid, phthalic acid, maleic acid, oxalic acid, citric acid, malic acid, malonic acid, and glutaric acid. Further, basic salts such as ammonia, ethylene diamine, and TMAH (tetramethyl ammonium hydroxide) can be also used. Neutral amino acids such as glycine and alanine can be also added. The content of the water-soluble Cu complex-forming agent is preferably equal to or more than 0.0005% by mass to equal to or less than 2.0% by mass based on the total amount of the first CMP slurry. When its content is equal to or more than 0.0005% by mass to equal to or less than 2.0% by mass, Cu can be polished at high rate, and simultaneously the surface of the wiring layer can be prevented from dishing and corrosion upon polishing. The more preferable content of the water-soluble Cu complex-forming agent, though varying depending on a Cu film or a difference in the composition of Cu alloy, is equal to or more than 0.0075% by mass to equal to or less than 1.5% by mass based on the total amount of the first CMP slurry.

### (Oxidizing Agent)

For example, the oxidizing agent includes persulfate and hydrogen peroxide. For example, the persulfate includes ammonium persulfate and potassium persulfate. The concentration of the oxidizing agent is preferably 0.001 to 2% by mass, more preferably 0.01 to 2% by mass, and further preferably 0.05 to 1.5% by mass, based on the total amount of the first CMP slurry. When the oxidizing agent is incorporated in this range, the rates of polishing of the Cu or Cu alloy film and the barrier metal film can be established in a suitable range.

### (Surfactant)

As nonionic surfactants, for example, polyvinyl pyrrolidone (PVP), acetylene glycol, ethylene oxide adducts thereof, acetylene alcohol, silicone-based surfactants, polyvinyl alcohol, polyvinyl methyl ether, and hydroxyethyl cellulose can be used. Further, anionic or cationic surfactants can be included. The anionic surfactants include dodecylbenzene sulfonate, high-molecular-weight polyacrylate or the like, and the cationic surfactants include, for example, fatty amine salts and fatty ammonium salts. The surfactants described above can be used independently or as a combination of two or more thereof. The content of the surfactant is preferably equal to or more than 0.001% by mass to equal to or less than 0.5% by mass based on the total amount of the first CMP slurry. By setting the content in this range, the surface of the wiring layer can be sufficiently prevented from dishing upon polishing. The content of the surfactant is more preferably equal to or more than 0.05% by mass to equal to or less than 0.3 based on the total amount of the first CMP slurry.

### (Colloidal Silica)

For example, the colloidal silica can be obtained by hydrolyzing silicon alkoxide compounds such as Si(OC₂H₅)₄, Si(sec-OC₄H₉)₄, Si(OCH₃)₄, and Si(OC₄H₉)₄ by the sol-gel process. The particle size of the colloidal silica is preferably 5 to 500 nanometers, more preferably 10 to 100 nanometers, and further preferably 20 to 50 nanometers. By using the colloidal silica having an average dispersion particle size in this range, a suitable polishing rate can be achieved.

The content of the colloidal silica is preferably 1 to 10% by mass and more preferably 2 to 5% by mass, based on the total amount of the first CMP slurry. A colloidal silica content of higher than 10% by mass can increase the polishing rate. However, it is not preferable from the viewpoint of costs. Meanwhile, a colloidal silica content of lower than 1% by mass is not preferable either, because the throughput of semiconductor manufacturing is low due to a low polishing rate.

### (pH of the First CMP Slurry)

The pH of the first CMP slurry is preferably more than 7 to equal to or less than 13 and more preferably 8 to 11. When the pH is in this range, a suitable polishing rate can be achieved. The pH adjusting agent includes, for example, an organic base, an inorganic base and an inorganic acid. The organic base includes, for example, tetramethyl ammonium hydroxide (TMAH) and triethylamine. The inorganic base includes, for example, ammonia, potassium hydroxide, and sodium hydroxide. The inorganic acid includes, for example, nitric acid and sulfuric acid.

### [Second CMP Slurry (CMP Slurry of the Embodiment)]

As described above, the second CMP slurry, which is used in the second CMP process of removing a barrier metal film, a Cu or Cu alloy film, and a second insulating film in the semiconductor device manufacturing method according to the present embodiment, contains basic element materials such as abrasive grains used commonly in the first CMP slurry, and further contains a specific water-soluble polymer having a weight-average molecular weight of 1,000,000 to 10,000,000 and β-cyclodextrin as other essential components. When components contained in the first CMP slurry are also contained in the second CMP slurry, the content of such components in the second CMP slurry can be substantially the same as in the first CMP slurry. The preferable range of pH of the second CMP slurry is the same as in the first CMP slurry and is preferably set alkaline by compounding the same pH adjusting agent as in the first CMP slurry.

### (Water-Soluble Polymer)

The water-soluble polymer includes, for example, polyacrylic acid, polyacrylate, polymethacrylic acid, polymethacrylate, an acrylic acid-methacrylic acid polymer, and a salt of an acrylic acid-methacrylic acid polymer. As the water-soluble polymer used in the CMP slurry of the present embodiment, a single polymer or a mixture of two or more polymers selected from the group mentioned above can be used, and it is important that the weight-average molecular weight thereof is 1,000,000 to 10,000,000. When the weight-average molecular weight is 1,000,000 or more, an effect of preventing fang, which easily occurs on a polished surface, is exhibited, an effect of reducing the number of scratches can also be achieved, and the surface of the wiring layer can also be prevented from dishing. When the weight-average molecular weight is 10,000,000 or less, the colloidal silica in the second CMP slurry can be prevented from aggregating, thereby reducing the number of scratches on the polished surface. When the weight-average molecular weight is 1,000,000 to 10,000,000, the viscosity of the second CMP slurry can be regulated in such a range that while the colloidal silica can be prevented from aggregating, the colloidal silica can be uniformly maintained, and also in such a range that the silica can be dropped onto a polishing table, thereby improving operability. Because the water-soluble polymer is one kind of large anion group, it is considered that the polymer, when compounded with a pH adjusting agent, will attract pH adjusting agent-derived cations around itself, and this cation group further attracts the colloidal silica thereby enabling the colloidal silica as abrasive grains to be uniformly maintained, thus obtaining excellent polishing characteristics.

The concentration of this water-soluble polymer is preferably 0.0001 to 0.5% by mass and more preferably 0.01 to 0.1% by mass, based on the total amount of the second CMP slurry. When the concentration of the water-soluble polymer is equal to or less than 0.5% by mass, the cost can be reduced and excellent viscosity for handling can be realized. Meanwhile, when the concentration is equal to or more than 0.0001% by mass, the rate of polishing of the second insulating film (SiO₂ film) can be prevented from decreasing, and not only an effect of preventing fang, but also an effect of reducing the number of scratches on a polished surface can be favorably achieved.

### (β-Cyclodextrin)

The cyclodextrin used is β-cyclodextrin among α-, β- and γ-cyclodextrins. β-cyclodextrin has a particularly strong action on low dielectric materials such as SiOC film and is considered to exhibit an effect of suppressing fang by contacting with a hydrophobic low-dielectric material film directly or via interaction with other components in the second CMP slurry, thereby reducing the hydrophobicity of the surface of the film and shifting it toward the direction of hydrophilicity. This β-cyclodextrin is assumed to contribute to the prevention of aggregation of colloidal silica by contacting with colloidal silica and electrically neutralizing the colloidal silica.

The concentration of β-cyclodextrin is preferably 0.001 to 0.5% by mass and more preferably 0.01 to 0.1% by mass, based on the total amount of the second CMP slurry. When the concentration of β-cyclodextrin is equal to or more than 0.001% by mass, a particularly favorable rate of polishing of the second insulating film can be realized, and consequently the throughput of semiconductor device manufacturing can be improved. Even if the concentration of β-cyclodextrin exceeds 0.5% by mass, its effect of improving the rate of polishing is not high, and thus the upper-limit of concentration is set preferably at 0.5% by mass from the viewpoint of costs.

### (Washing Solution)

Preferably, the semiconductor device manufacturing method is provided with a washing process performed successively after the second CMP process. As a washing solution used in the washing process, it is possible to use a solution in which Cu complexes and Cu oxides can be dissolved, such as an acidic solution based on citric acid or oxalic acid or an alkaline solution of TMAH or the like.

### [Semiconductor Device Manufacturing Method]

The semiconductor device manufacturing method according to the present embodiment includes first forming a first insulating film above a semiconductor substrate, second forming, on the first insulating film, a second insulating film having a higher dielectric constant than that of the first insulating film, forming a wiring concave portion from the second insulating film to the first insulating film, forming a barrier metal film on the inner surface of the concave portion and the surface of the second insulating film, depositing copper or copper alloy on the barrier metal film, to be embedded in the concave portion covered with the barrier metal film, thereby forming a wiring material-deposited layer, polishing and removing the wiring material-deposited layer flatly by first chemical mechanical polishing until the barrier metal film is exposed, and after the first chemical mechanical polishing, polishing and removing the barrier metal film and the second insulating film flatly by second chemical mechanical polishing until the first insulating film is exposed, where the second chemical mechanical polishing is conducted by using the CMP slurry of the present embodiment.

The semiconductor device manufacturing method performed by using the first CMP slurry and the second CMP slurry is described next in detail with reference to the drawings.

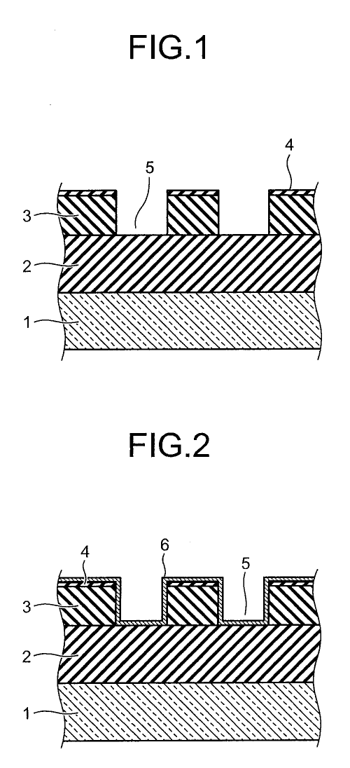

As shown in FIG. 1, an insulating layer 2 consisting of SiO₂ is first formed on a semiconductor substrate 1 on which a semiconductor element (not shown) is formed. A first insulating film 3 is formed on the insulating layer 2 by a chemical vapor deposition (CVD) method, a spin-coating method or the like. For example a low-dielectric material such as SiOC formed by a spin on glass (SOG) method, the CVD method or the like is mainly used as the material constituting the first insulating film 3. A second insulating film 4 consisting of SiO₂ or the like as a cap insulating film is formed on the first insulating film 3, and a concave portion (wiring groove) 5 is formed in areas from the second insulating film 4 to the first insulating film 3.

As shown in FIG. 2, a barrier metal is then deposited on the surface of the first insulating film 3 having the concave portion 5 formed therein as described above, thereby forming a barrier metal film 6 on the inner surface of the concave portion 5. At this time, the barrier metal film 6 is also formed on the second insulating film 4. The barrier metal film 6 is a barrier film by which copper or copper alloy to be embedded in the concave portion 5 is prevented from diffusing into the first insulating film 3.

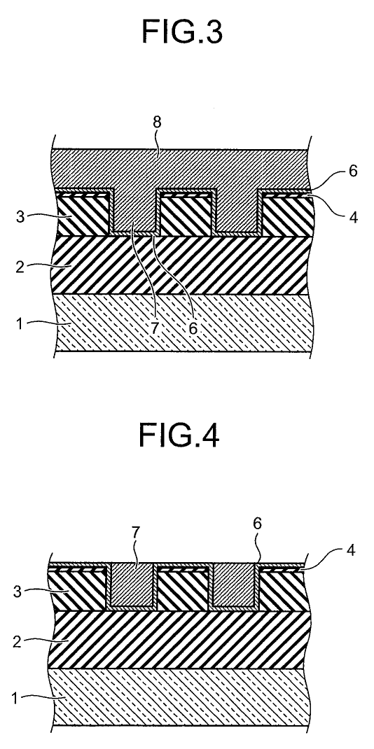

Thereafter, copper or copper alloy for forming a lower-layer wiring layer 7 is deposited in the concave portion 5 by electrolytic plating, sputtering method or the like, as shown in FIG. 3. In this case, it is difficult in manufacturing to deposit copper or copper alloy in only the concave portion 5, so that as a result of deposition, a wiring material-deposited layer 8 consisting of copper or copper alloy is formed such that entire surfaces of both the concave portion 5 and the barrier metal film 6 are covered therewith, as shown in FIG. 3.

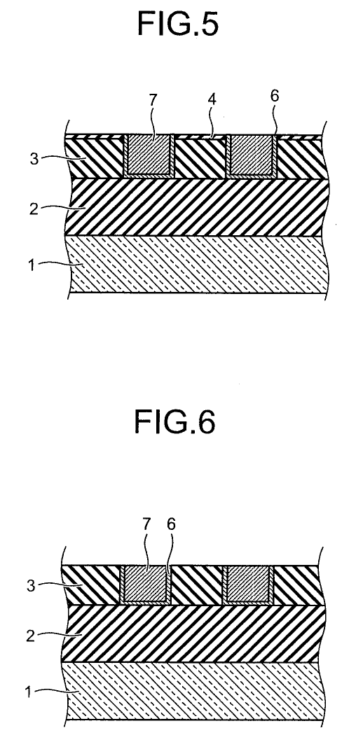

Because the wiring material-deposited layer 8 and the barrier metal film 6 formed outside the concave portion 5 are a redundant portion, the redundant portion needs to be removed to planarize the surface of the laminated film. Accordingly, the laminated film is subjected to a CMP process. This CMP process is performed in two divided processes, that is, the first and second CMP processes. As shown in FIGS. 3 to 4, the first CMP process is a rough grinding process of removing most of the wiring material-deposited layer 8. As shown in FIGS. 4 to 6, the second CMP process is a final polishing process of removing the remaining wiring material-deposited layer 8, the barrier metal film 6 and the second insulating film 4 to expose the first insulating film 3 and simultaneously planarizing the entire surface of a wafer. The second CMP process is also called touch-up polishing.

The first CMP slurry having the composition described above is used in the first CMP process, and thereafter the second CMP slurry having the composition described above is used in the second CMP process.

By using the CMP slurry (second CMP slurry) of the present embodiment in the second CMP process, the second insulating film 4 consisting of SiO₂ can be favorably polished in the polishing process in FIGS. 4 to 6 (the second CMP process). Fang, which easily occurs at the time of exposing the first insulating film 3, can be suppressed by the CMP slurry of the present embodiment, and the number of scratches easily generated in each of the lower-layer wiring layer 7 can also be reduced.

### EXAMPLES

### Examples of the present invention are explained below

Note that the following Examples are only illustrative and should not be construed as a limitation on the present invention.

### Examples 1 to 5

The first CMP slurry used in the first CMP process was prepared according to the components and compounding ratio shown in Table 1 below, and the first CMP slurry was used as the first CMP slurry commonly in Examples 1 to 5.

TABLE 1
Composition of the first CMP slurry

| Components | | Content (mass %) |
|---|---|---|
| Water | | Balance |
| Water-insoluble | Quinaldinic acid | 0.3 |
| Cu complex- | Quinolinic acid | 0.3 |
| forming agent | | |
| Water-soluble Cu | Alanine | 0.3 |
| complex-forming | Oxalic acid | 0.1 |
| agent | | |
| Oxidizing agent | Ammonium | 2.5 |
| | persulfate | |
| Surfactant | Potassium | 0.03 |
| | dodecylbenzene | |
| | sulfonate | |
| | Polyvinyl | 0.03 |
| | pyrrolidone | |
| Abrasive grain | Colloidal silica | 0.75 |
| pH adjusting | KOH | (Adjusted to pH 9) |
| agent | | |

The second CMP slurry used in the second CMP process in each of the Examples 1 to 5 was prepared according to the components and compounding ratio shown in Table 2 below.

### Comparative Examples 1 to 4

Similarly to the Examples 1 to 5, the first CMP slurry used for the first CMP process, prepared according to the components and compounding ratio shown in Table 1 was commonly used in Comparative Examples.

The second CMP slurry used in the second CMP process in Comparative Examples 1 to 4 was prepared according to the components and compounding ratio shown in Table 3 below.

The CMP slurries in the Examples 1 to 5 and the Comparative Examples 1 to 4 were used to manufacture semiconductor devices in the following manner.

The following manufacturing process is described with reference to FIGS. 1 to 6. The insulating layer 2 consisting of SiO₂ was arranged on a semiconductor substrate 1 on which a semiconductor element (not shown) was formed. A low-dielectric insulating film as the first insulating film 3 and the second insulating film 4 as cap insulating film were formed sequentially on the insulating layer 2, to form a laminated insulating film. As the first insulating film 3, an SiOC film having a dielectric constant of less than 2.8 was formed with a thickness of 180 nanometers.

As the second insulating film 4, an SiO₂ film of 30 nanometers in thickness was formed. The concave portion (wiring groove) 5 for wiring was formed in areas from the second insulating film 4 to the first insulating film 3. Thereafter, a Ta film was deposited by a common process with a thickness of 5 nanometers as the barrier metal film 6 on the entire surface. Thereafter, a Cu film 8 was deposited with a thickness of 550 nanometers such that the barrier metal film 6 was covered therewith.

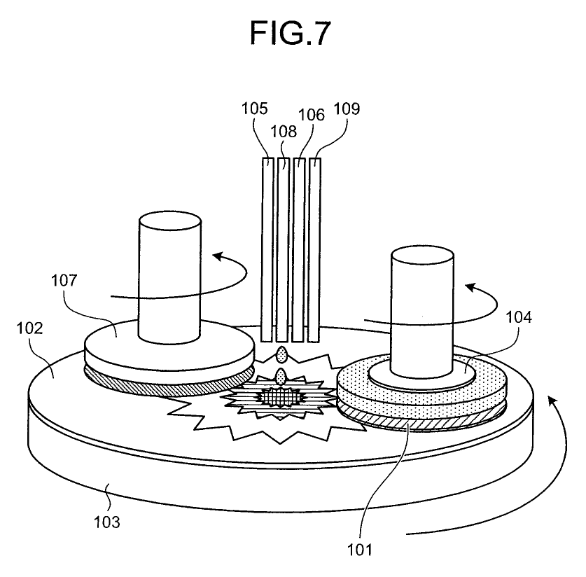

As shown in FIG. 7, a semiconductor substrate 101 of 300 millimeters in diameter on which a Cu film was deposited as described above was then prepared, and the semiconductor substrate 101 was subjected to the first and second CMP processes successively on the same polishing table. That is, the semiconductor substrate was subjected successively to the first process in which a redundant portion of the Cu film was removed while the Cu film of the semiconductor substrate 101 was achieved firmly to a polishing cloth 102, to the second process in which the barrier metal film, the Cu film and the second insulating film were removed, and to the third process in which the semiconductor substrate 101 after polishing was washed. At this time, a turntable 103 to which IC₁₀₀₀ (trade name, manufactured by Nitta Haas Inc.) was attached as the polishing cloth 102 was rotated at 80 revolutions per minute (rpm), while a top ring 104 that held the semiconductor substrate 101 as a sample was used to abut the semiconductor substrate 101 against the polishing cloth 102 with a polishing loading of 200 gf/cm².

The number of revolutions of the top ring 104 was 81 rpm, and the first CMP slurry for removing a redundant portion of the Cu film was fed at a flow rate of 300 cc/min from a first polishing-solution feeding nozzle 105, to carry out polishing until the redundant Cu film was removed. Thereafter, feeding from the first polishing-solution feeding nozzle 105 was stopped, and the semiconductor substrate 101 as a sample while being abutted against the polishing cloth 102 was continuously supplied with purified water at a flow rate of 300 cc/min from a purified-water feeding nozzle 106 and allowed to slide on the polishing cloth 102 for 10 seconds. With this state, conditioning of the polishing cloth 102 was performed by a diamond dresser 107, and feeding from the purified-water feeding nozzle 106 was stopped.

Subsequently, the second CMP slurry in each of the examples was fed at a flow rate of 300 cc/min from a second polishing-solution feeding nozzle 108, and polishing was performed until the second insulating film 4 under the barrier metal film 6 was eliminated. Thereafter, the feeding of the second CMP slurry from the second polishing-solution feeding nozzle 108 was stopped, and the semiconductor substrate 101 and the polishing cloth 102 while being allowed to slide on each other were continuously supplied with purified water at a flow rate of 300 cc/min from the purified-water feeding nozzle 106. With this state, conditioning of the polishing cloth 102 was performed by the diamond dresser 107. Subsequently, feeding from the purified-water feeding nozzle 106 was stopped, and while an alkali washing solution based on TMAH as a washing solution for a washing process was fed at a flow rate of 300 cc/min from a third polishing solution feeding nozzle 109, the semiconductor substrate 101 held on the top ring 104 was allowed to slide on the polishing cloth 102 for 30 seconds with a polishing load of 200 gf/cm². Thereafter, the semiconductor substrate 101 as a sample was allowed to pass through a washing unit (not shown) and dried with IPA (isopropyl alcohol).

In addition to the semiconductor device manufacturing by the above processes, another semiconductor device was manufactured using the CMP slurries in the Examples 1 to 5 and the Comparative Examples 1 to 4 in the same manner as in the semiconductor device manufacturing method except that the first CMP process and the second CMP process were conducted by using different polishing tables.

Hereinafter, polishing by the first CMP process and the second CMP process conducted continuously with the same polishing table is referred to as continuous polishing, while polishing by the first CMP process and the second CMP process conducted with different polishing tables is referred to as discontinuous polishing.

### Evaluation of CMP Slurry

Polishing characteristics of the CMP slurry in each example were evaluated by examining each substrate sample on which a wiring pattern with a wiring width of 0.06 micrometer at wiring intervals of 0.06 micrometer (wiring coverage 50%) was formed. The size of fang (width size (nanometers)) was evaluated by measuring the edge of the low-dielectric insulating film (first insulating film) in a field region adjacent to the wiring pattern by an atomic force microscope (AFM). The number of generated scratches over the entire surface of a polished surface of the semiconductor substrate of 300 millimeters in diameter was evaluated with a defect evaluation apparatus (trade name: IS2700, manufactured by Hitachi High-Technologies Corporation). The rate of polishing of the SiO₂ film (second insulating film) was measured by separately forming an SiO₂ film on the entire surface of the semiconductor substrate and subjecting the SiO₂ film to polishing. The rate of polishing of the SiO₂ film was measured in each of the discontinuous polishing and continuous polishing. The measurement results are shown in Tables 2 and 3.

TABLE 2
Second CMP slurry (Examples)

| | | | Examples | | | | |
|---|---|---|---|---|---|---|---|
| | | | 1 | 2 | 3 | 4 | 5 |
| Components | Water | | Balance | Balance | Balance | Balance | Balance |
| (mass %) | Quinaldinic acid | | — | — | — | — | 0.05 |
| | Maleic acid | | 0.8 | 0.8 | 0.8 | 0.8 | 0.8 |
| | Hydrogen peroxide | | 0.2 | 0.2 | 0.2 | 0.2 | 0.2 |
| | (oxidizing agent) | | | | | | |
| | Colloidal silica | | 4 | 4 | 4 | 4 | 4 |
| | Polyacrylic | mw: 1,000,000 | 0.01 | 0.1 | — | — | 0.1 |
| | acid | mw: 10,000,000 | — | — | 0.1 | 0.1 | — |

| | | | | | |
|---|---|---|---|---|---|
| β-cyclodextrin | 0.1 | 0.1 | 0.1 | 0.01 | 0.1 |

| | | | | | |
|---|---|---|---|---|---|
| pH (pH adjusting agent: KOH) | 10 | 10 | 10 | 10 | 10 |
| Fang (nm)* | 15 | 12 | 10 | 16 | 18 |
| Number of scratches* | 12 | 10 | 8 | 25 | 8 |
| SiO₂ polishing rate | 58.2 | 60.6 | 68.2 | 52.5 | 50.7 |
| (discontinuous polishing) nm/min | | | | | |
| SiO₂ polishing rate (continuous | 54.2 | 57.1 | 63 | 47.3 | 46.1 |
| polishing) nm/min | | | | | |

*Measurements in continuous polishing

TABLE 3
Second CMP slurry (Comparative Examples)

| | | | Comparative Examples | | | |
|---|---|---|---|---|---|---|
| | | | 1 | 2 | 3 | 4 |
| Components | Water | | Balance | Balance | Balance | Balance |
| (mass %) | Quinaldinic acid | | — | — | — | — |
| | Maleic acid | | 0.8 | 0.8 | 0.8 | 0.8 |
| | Hydrogen peroxide | | 0.2 | 0.2 | 0.2 | 0.2 |
| | (oxidizing agent) | | | | | |
| | Colloidal silica | | 4 | 4 | 4 | 4 |
| | Polyacrylic | mw: 1,000,000 | — | — | — | 0.1 |
| | acid | mw: 10,000,000 | — | — | 0.1 | — |

| | | | | |
|---|---|---|---|---|
| β-cyclodextrin | — | 0.1 | Cellulose | 0.1 |
| | | | 0.1 | |

| | | | | |
|---|---|---|---|---|
| pH (pH adjusting agent: KOH) | 10 | 10 | 10 | 10 |
| Fang (nm)* | 53 | 18 | 35 | 50 |
| Number of scratches* | 255 | 35 | 40 | 102 |
| SiO₂ polishing rate (discontinuous | 29.9 | 32 | 25 | 38 |
| polishing) nm/min | | | | |
| SiO₂ polishing rate (continuous | 24 | 29.1 | 21.25 | 35 |
| polishing) nm/min | | | | |

*Measurements in continuous polishing

As shown in Table 2, a compositional feature of the CMP slurry in the Example 1 is the simultaneous inclusion of 0.01% by mass of polyacrylic acid having a weight-average molecular weight (mw) of 1,000,000 and 0.1% by mass of β-cyclodextrin. The CMP slurry in the Example 2 is different from this slurry in the Example 1 in that the content of polyacrylic acid having a weight-average molecular weight (mw) of 1,000,000 is increased to 0.1% by mass. By this increase in the content of polyacrylic acid, there are recognized improvements in the effect of suppressing fang, the effect of reducing the number of scratches, and the effect of improving the polishing rate of SiO₂.

The Examples 2 and 3 are the same in that the content of polyacrylic acid is 0.1% by mass. However, the Example 3 is different from the Example 2 in that polyacrylic acid having a higher weight-molecular weight (mw) of 10,000,000 is used. By this increase in the weight-average molecular weight, there are recognized improvements in all of the effect of suppressing fang, the effect of reducing the number of scratches, and the effect of improving the polishing rate of SiO₂, among which the improvement in the effect of reducing the number of scratches is particularly significant.

The Example 4 is different from the Example 3 in that the content of β-cyclodextrin is decreased to 0.01% by mass. By this decrease in the content of β-cyclodextrin, all of the effect of suppressing fang, the effect of reducing the number of scratches, and the effect of improving the polishing rate of SiO₂ are decreased as compared with those in the Example 3, and particularly the effect of reducing the number of scratches tends to be lower.

The Example 5 is different from the Example 2 in only the feature that quinaldinic acid is added with an amount of 0.05% by mass. This quinaldinic acid is an organic acid, and is a water-insoluble Cu complex-forming agent incorporated into the first CMP slurry for polishing a redundant portion of the Cu film. It is considered that the organic acid, when contacted with an SiO₂ film, is adsorbed onto SiO₂, to decrease the polishing friction of the SiO₂ film. As compared with the evaluation results in the Example 2, the evaluation results other than the effect of reducing the number of scratches are lower, and particularly the rate of polishing of SiO₂ film tends to be lower. However, the lowering tendency is in a very small range, so that it can be confirmed that the CMP slurry of the embodiment of the present invention has an effect of suppressing the influence of the organic acid.

Meanwhile, in the Comparative Example 1, neither polyacrylic acid nor β-cyclodextrin is contained as shown in Table 3. As a result, all of the evaluation results are significantly lower than those in the Examples 1 to 5, and it can be understood that the increase in the number of scratches becomes significant.

In the Comparative Example 2, polyacrylic acid is not contained, and β-cyclodextrin is contained in an amount of 0.1% by mass. By this inclusion of β-cyclodextrin, the effect of suppressing fang and the effect of reducing the number of scratches tend to be improved to some extent, however, it is only at an insufficient level, and the effect of improving the polishing rate of SiO₂ film is hardly achieved.

In the Comparative Example 3, polyacrylic acid having a weight-average molecular weight of 10,000,000 is contained in an amount of 0.1% by mass. By this inclusion of polyacrylic acid, as is the case with the inclusion of β-cyclodextrin, the effect of suppressing fang and the effect of reducing the number of scratches tend to be improved to some extent, however, it is only at an insufficient level, and the effect of improving the polishing rate of SiO₂ film is hardly achieved.

In the Comparative Example 4, both polyacrylic acid and β-cyclodextrin are contained. However, the weight-average molecular weight of the polyacrylic acid is as very small as 100,000. As a result, all of the evaluation results are low, and it can be seen that particularly the number of scratches tends to increase.

As described above, the CMP slurries in the Examples 1 to 5 are superior to the CMP slurries in the Comparative Examples 1 to 4 in the effect of suppressing fang and in the effect of reducing the number of scratches, and have increased the effect of improving the polishing rate of SiO₂ film (second insulating film), that is, the ability to reliably scrape the SiO₂ film to expose the SiOC film (first insulating film). This is a synergistic effect that can be achieved first by simultaneously using polyacrylic acid having a weight-average molecular weight of 1,000,000 to 10,000,000 (water-soluble polymer) and β-cyclodextrin.

As described above, the CMP slurry of the above embodiment can prevent fang, reduce the number of scratches, and prevent the polishing rate of the second insulating film (SiO₂ film) from decreasing, thereby yielding an excellent polished surface, in the CMP process in a semiconductor device manufacturing method. Accordingly, improvements in throughput and yield in semiconductor device manufacturing can be realized. Further, according to the semiconductor device manufacturing method, semiconductor devices excellent in reliability can be efficiently manufactured. Therefore, according to the above embodiment, semiconductor devices excellent in quality can be manufactured inexpensively, thereby making considerable contribution to the field of semiconductor manufacturing.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A chemical mechanical polishing slurry comprising:
at least one water-soluble polymer selected from a group consisting of polyacrylic acid, polymethacrylic acid and a salt thereof each having a weight-average molecular weight of 1,000,000 to 10,000,000;
β-cyclodextrin;
colloidal silica; and
water.

2. The slurry according to claim 1, wherein a content of the water-soluble polymer is 0.0001 to 0.5% by mass based on a total amount of the slurry.

3. The slurry according to claim 1, wherein a content of β-cyclodextrin is 0.001 to 0.5% by mass based on the total amount of the slurry.

4. The slurry according to claim 1, further comprising a pH adjusting agent, and wherein
the slurry is alkaline.

5. The slurry according to claim 4, wherein pH of the slurry is more than 7 and equal to or less than 13.

6. A semiconductor device manufacturing method comprising:
forming a first insulating film above a semiconductor substrate;
forming, on the first insulating film, a second insulating film having a higher dielectric constant than that of the first insulating film;
forming a wiring concave portion from the second insulating film to the first insulating film;
forming a barrier metal film on an inner surface of the concave portion and a surface of the second insulating film;
depositing copper or copper alloy on the barrier metal film so as to embed the concave portion covered with the barrier metal film, thereby forming a wiring material-deposited layer;
polishing flatly and removing the wiring material-deposited layer by a first chemical mechanical polishing until the barrier metal film is exposed; and
polishing flatly and removing the barrier metal film and the second insulating film by a second chemical mechanical polishing until the first insulating film is exposed, wherein
the second chemical mechanical polishing is conducted by using a chemical mechanical polishing slurry including at least one water-soluble polymer selected from a group consisting of polyacrylic acid, polymethacrylic acid, and a salt thereof each having a weight-average molecular weight of 1,000,000 to 10,000,000, β-cyclodextrin, colloidal silica, and water.

7. The method according to claim 6, wherein the first chemical mechanical polishing and the second chemical mechanical polishing are conducted on a same polishing table.

8. The method according to claim 6, further comprising washing the polished semiconductor substrate on the polishing table after the second chemical mechanical polishing.

9. The method according to claim 8, wherein the washing is conducted using a washing solution capable of dissolving Cu complexes and Cu oxides, the washing solution being any one of an acidic solution based on citric acid or oxalic acid, and an alkaline solution of tetramethyl ammonium hydroxide.

10. The method according to claim 7, further comprising conditioning a polishing cloth disposed on the polishing table by supplying purified-water between the first chemical mechanical polishing and the second chemical mechanical polishing.

11. The method according to claim 8, further comprising conditioning a polishing cloth disposed on the polishing table by supplying purified-water between the second chemical mechanical polishing and the washing.

12. The method according to claim 6, wherein the first insulating film is a hydrophobic low-dielectric material film.

13. The method according to claim 6, wherein the first insulating film is SiOC film.

14. The method according to claim 6, wherein the second insulating film is SiO₂ film.

15. The method according to claim 6, wherein a content of the water-soluble polymer is 0.0001 to 0.5% by mass based on a total amount of the slurry.

16. The method according to claim 6, wherein a content of β-cyclodextrin is 0.001 to 0.5% by mass based on a total amount of the slurry.

17. The method according to claim 6, wherein the slurry further includes a pH adjusting agent, and is alkaline.

18. The method according to claim 17, wherein the pH of the slurry is more than 7 and equal to or less than 13.

19. The method according to claim 6, wherein a chemical mechanical polishing slurry used in the first chemical mechanical polishing includes an organic acid.

20. The method according to claim 19, wherein the organic acid is capable of forming a complex with Cu in the first chemical mechanical polishing.
